(19) United States
(12) Patent Application Publication
(10) Pub. No.: US 2012/0000421 A1
(43) Pub. Date: Jan. 5, 2012

(54) CONTROL APPARATUS FOR PLASMA IMMERSION ION IMPLANTATION OF A DIELECTRIC SUBSTRATE

(75) Inventors: Timothy Miller, Ipswich, MA (US); Vikram Singh, North Andover, MA (US); Ludo Godet, Boston, MA (US); Christopher J. Leavitt, Gloucester, MA (US)

(73) Assignee: Varian Semicondutor Equipment Associates, Inc., Gloucester, MA (US)

(21) Appl. No.: 12/829,794

(22) Filed: Jul. 2, 2010

(51) Int. Cl. C23C 14/48; C23C 14/50; C23C 14/52; H05F 3/00

(52) U.S. Cl. 118/712; 361/213; 118/723 R

(57) ABSTRACT

A control apparatus for plasma immersion ion implantation of a dielectric substrate which includes an electrode disposed above a generated plasma in a plasma chamber. The electrode is biased with negative voltage pulses at a potential that is higher than a potential of a substrate or cathode configured to receive ion implantation. The electrode is more negative to give the electrons generated as secondary electrons from the electrode sufficient energy to overcome the negative voltage of the high voltage sheath around the substrate thereby reaching the substrate. These electrons are accelerated toward the substrate to neutralize charge build-up on the substrate.

### BACKGROUND OF THE INVENTION

1. Field of the Invention

Embodiments of the invention relate to the field of plasma processing systems. More particularly, the present invention relates to an apparatus and method for improving and regulating voltage coupling for insulating target substrates used in plasma immersion ion implantation.

2. Discussion of Related Art

Plasmas are used in a variety of ways in semiconductor processing to implant wafers or substrates with various dopants, to deposit or to etch thin films. Such processes involve the directional deposition or doping of ions on or beneath the surface of a target substrate. Other processes include plasma etching, where the directionality of the etching species determines the quality of the trenches to be etched.

Generally, plasma immersion ion implantation (PIII), also referred to as plasma doping (PLAD), implants dopants into a substrate. The plasma is generated by supplying energy to a neutral gas introduced into a chamber to form charged carriers which are implanted into the target substrate. PLAD systems are typically used when shallow junctions are required in the manufacture of semiconductor devices where lower ion implant energies confine the dopant ions near the surface of the target substrate or wafer. In these situations, the depth of implantation is related to the voltage applied between the wafer and an anode within a plasma processing chamber of a PLAD system or tool. In particular, a wafer is positioned on a platen, which functions as a cathode, within the chamber. An ionizable gas containing the desired dopant materials is introduced into the plasma chamber. The gas is ionized by any of several methods of plasma generation, including, but not limited to DC glow discharge, capacitively coupled RF, inductively coupled RF, etc.

Once the plasma is generated, there exists a plasma sheath between the plasma and all surrounding surfaces, including the target substrate. The sheath is essentially a layer in the plasma which has a greater density of positive ions (i.e. excess positive charge), as compared to an opposite negative charge on the surface of the target substrate. The platen and substrate are then biased with a negative voltage in order to cause the ions from the plasma to cross the plasma sheath and be implanted into or deposited on the wafer at a depth proportional to the applied bias voltage.

Implantation using a PLAD tool is typically limited to conducting substrates or a semiconductive (e.g., Si) workpiece due to the ability to bias a conductive substrate to attract ions across the plasma sheath for implantation therein. To fabricate certain types of devices, there is a need to implant particular dopants in insulating or insulator substrates such as glass, quartz, etc. However, it is difficult to couple voltage through an insulating substrate in order to maintain the proper biasing of the substrate to attract the ions across the plasma sheath for implantation. In particular, for relatively thick insulating substrates, voltage coupling is limited by the low capacitance of the insulator substrate as compared to the capacitance of the plasma sheath above the surface of the substrates. This leads to a voltage divider circuit where most of the voltage is dropped across the substrate. For thin insulating substrates used in, for example, flat panel displays, a reasonable portion of the voltage is coupled to the substrate, but is quickly degraded. This is due, in part, to positive charging of the insulator substrate when the ions are implanted as well as the generation of secondary electrons when the ions strike the surface of the insulator substrate.

This is generally shown in FIG. 1 which is a functional diagram illustrating certain of the voltage potentials in a typical PLAD tool. An insulator substrate 1 is disposed on a conductive platen 2. Plasma 3 is generated by the introduction of a reactive gas into the chamber as is well known in the art. The sheath 4 between the generated plasma and the surface of insulator substrate 1 has an effective implant voltage (V_{eff}) given by:

$${V}_{eff} = {V}_{0} ( \frac{1 - a ( t ) \text{/} {V}_{o}}{1 + b ( t )} )$$

where a(t) represents the drop in effective voltage due to the surface charging of the insulator substrate 1 caused by the implanted ions together with the generated secondary electrons, and b(t) represents the capacitive divider of the insulator substrate 1 and sheath 4. Because the target substrate is an insulator, the properties of sheath 4 changes and a capacitive divider may exist thereby reducing the effective voltage. In addition, the charge build-up on the surface of the insulator target substrate further reduces the effective voltage. If the effective voltage is too small, then the implantation process may be compromised. Thus, there is a need to reduce the charge build-up on the surface of an insulator target substrate used in a PLAD system which maintains the effective voltage to provide the desired implant characteristics.

### SUMMARY OF THE INVENTION

Exemplary embodiments of the present invention are directed to a control apparatus for plasma immersion ion implantation of a dielectric substrate and an associated method. In an exemplary embodiment, a plasma processing tool comprises a plasma chamber configured to generate a plasma having ions from a gas introduced into the chamber. A platen is configured to support and electrically connect to an insulator substrate for plasma doping. The platen is connected to a voltage source supplying negative bias voltage pulses at a first potential to the platen and to the substrate. An electrode is disposed above the generated plasma and receives negative bias voltage pulses at a second potential where the second potential is more negative than the first potential in order to give the electrons provided from the second electrode sufficient energy to overcome the negative voltage of the high voltage sheath around the substrate thereby reaching the substrate. When the ions strike the electrode, secondary electrons are generated which are accelerated toward the substrate at the second potential to neutralize charge build-up on the substrate.

A method for neutralizing charge build-up on a surface of an insulator target substrate in a plasma processing tool is disclosed comprising providing a reactive gas to a chamber and exciting the reactive gas to generate a plasma having ions. First bias voltage pulses are applied to an insulator substrate disposed in the chamber. Second bias voltage pulses re applied to an electrode disposed above the plasma where the second bias voltage pulses have a higher potential than the first bias voltage pulses to attract the ions toward the electrode. Secondary electrons are generated when the attracted ions strike a surface of the electrode. The secondary electrons are accelerated-toward the insulator substrate to neutralize charge build-up present on a surface of the substrate.

### BRIEF DESCRIPTION OF THE DRAWINGS

FIG. 1 is a functional diagram illustrating certain of the voltage potentials in a typical PLAD system or tool.

FIG. 2 is a schematic illustration of a simplified PLAD system in accordance with an exemplary embodiment of the present disclosure.

FIG. 3 is a functional diagram of the exemplary PLAD system shown in FIG. 2 in accordance with an embodiment of the present disclosure.

FIG. 4 illustrates a simplified PLAD system that includes a closed loop control system in accordance with an exemplary embodiment of the present disclosure.

FIG. 5 is a functional diagram of the exemplary PLAD system shown in FIG. 4 in accordance with an exemplary embodiment of the present disclosure.

FIG. 5A illustrates voltage pulses applied to the electrode and substrate in accordance with an alternative exemplary embodiment of the present disclosure.

FIG. 6 is a graph illustrating the effect of a pulse applied to the electrode plate and the platen on the surface voltage of a target substrate in accordance with an exemplary embodiment of the present disclosure.

FIG. 7 illustrates graphs of the frequency of pulses and the corresponding impact on the surface voltage in accordance with an embodiment of the present disclosure.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

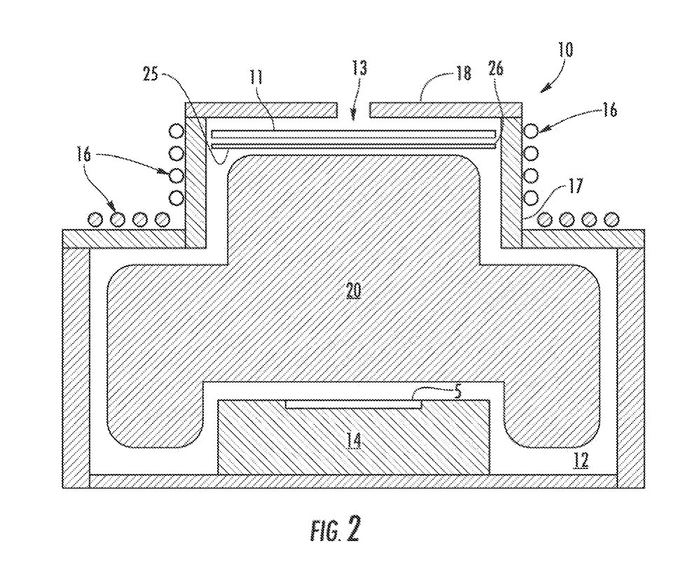

FIG. 2 is a schematic illustration of a simplified PLAD system or tool 10 in accordance with an exemplary embodiment of the present disclosure. The system 10 comprises a process chamber 12 having a pedestal or platen 14 to support an insulated target substrate 5. One or more reactive gases containing the desired dopant characteristics are fed into the process chamber 12 via a gas inlet 13 through a top plate 18 of the chamber. The reactive gas may be, for example, BF3, B2H6, PF5, etc. The reactive gas(es) may then be distributed uniformly via baffle 11 before entering the process chamber 12. A group of coils 16 which together with the walls of chamber 12 form an anode may couple radio frequency (RF) electrical power into the process chamber 12 through an aluminum oxide (Al₂O₃) window 17. The RF power produces a dopant-containing plasma 10 from the reactive gas(es). A bias voltage is applied to the target substrate 5 via the platen 14 to draw charged particles from the plasma 20. The platen 14 is electrically insulated from the chamber 10 and the target substrate is kept at a negative potential to attract the positively charged ions of the plasma. Typically, the substrate 12 is biased with a pulsed DC voltage to act as a cathode. As a result, dopant ions are extracted from the plasma 20 across a plasma sheath disposed between plasma 20 and a top surface of substrate 5. The ions are implanted into the substrate 5 during the bias pulse-on periods. Generally, an ion dose is the amount of ions implanted into the target substrate or the integral over time of the ion current. The bias voltage corresponds to the implantation depth of the ions which may also be influenced by the pressure and flow rate of the reactive gas introduced into chamber 12, duration of the bias voltage, etc.

The target substrate 5 may be an insulating substrate used in flat panel displays. The target substrate may also be, for example, low-temperature polycrystalline silicon (LTPS), thin film transistors (TFT), organic light emitting diodes (OLED), solar cells, etc. As mentioned above, because the target substrate is an insulator (e.g. glass, quartz, etc.), the sheath above the target becomes a capacitive divider due to the low capacitance of the target substrate 5 as compared to the capacitance of the sheath between the plasma and the surface of the target substrate 5. This reduces the effective implant voltage V_{eff} (given in Eq. 1 above) which is further reduced by the build-up of charge on the surface of the insulated target substrate 5. In particular, when target substrate 5 is biased with DC voltage pulses to attract the ions across the plasma sheath, charge tends to accumulate on the surface of substrate 5. When the pulsed-on cycles of the plasma implant process are relatively low, this charge build-up tends to be efficiently neutralized by electrons that are present in the plasma 20. However, when the pulsed-on cycles increase to achieve desired throughputs and to maintain doping levels that are required for some modern devices, there is a shorter period of time where the build-up on substrate 5 can be neutralized during the off cycles. Consequently, charge build-up occurs on the surface of substrate 5. This may result in a relatively high potential voltage on the substrate which causes doping non-uniformities, arcing, and device damage. In other words, both the charge build-up and the reduced effective voltage negatively effects the implantation process.

The build-up of charge on the surface of the insulating target substrate 5 may be neutralized by providing a source of electrons (negative charge) to substrate 5. This is accomplished by providing an electrode 25 which may be, for example, in the form of a plate disposed below and insulated from baffle 11 by insulating portion 26 since baffle 11 is typically at ground potential. The electrode 25 is a conducting material which is compatible with plasma environments and may be, for example, aluminum, low resistivity SiC or Silicon coated aluminum. Alternatively, electrode 25 may be integrally formed with baffle 11 in which case baffle 11 is electrically isolated from the walls of chamber 12 and is configured to maintain the desired electrode potential to neutralize the charge build-up on the surface of target substrate 5. Generally, the charge build-up on the substrate 5 is neutralized by generating secondary electrons as a result of ions striking the surface of electrode plate 25 which are accelerated toward the cathode (substrate 5) at the potential placed on electrode plate 25.

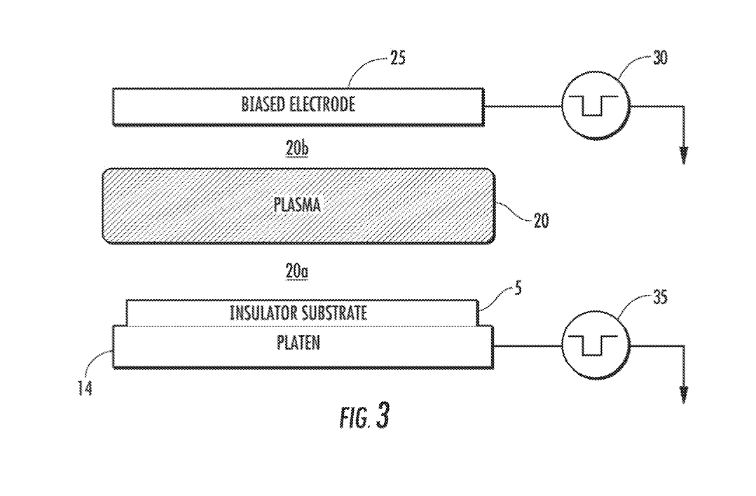

This may be better understood by turning to FIG. 3 which is a functional diagram showing just the interior of PLAD tool 10 to illustrate how the electrode plate 25 is used to generate secondary electrons in order to neutralize charge buildup on insulating substrate 5. It will be understood that the components shown in FIG. 2, but not included in FIG. 3 are excluded only for explanatory purposes. Electrode plate 25 is opposite the cathode formed by platen 14 and insulating substrate 5. Electrode plate 25 is negatively biased with a voltage pulse 30. The pulse 30 is synchronized with the bias voltage pulse 35 applied to platen 14 used to attract the ions from plasma 20 across sheath 20a into insulator substrate 5. However, because electrode plate 25 is negatively biased with a voltage that is higher than the potential of the surface of substrate 5, ions from the plasma 20 are attracted across sheath 20b to electrode plate 25. The ions that strike the surface of electrode plate 25 create secondary electrons and these secondary electrons are accelerated toward the cathode formed by insulator 5 and platen 14 at the potential placed on electrode plate 25 by voltage pulses 30.

When these secondary electrons reach sheath 20a, they are decelerated. Because the voltage of electrode plate 25 is slightly higher than that of the insulator substrate 5, the secondary electrons generated from the electrode plate will reach substrate 5 through the high voltage sheath around the substrate 5 with very low energy, for example, typically less than 100V. These electrons neutralize the surface charge built-up on substrate 5. Ideally, for every ion that gets implanted in substrate 5 which generates a positive charge that builds-up on the surface thereof, a secondary electron from electrode plate 25 reaches substrate 5 and neutralizes a corresponding positive charge. This yield of secondary electrons from electrode plate 25 may be maximized to provide sufficient neutralization of the charge build-up on the surface of substrate 5. This may be accomplished by ensuring that the area of electrode plate 25 is greater than the area of substrate 5. In addition, electrode plate 25 may be configured to have a surface roughness to increase the incident angle of electrode plate 25, thereby increasing secondary electron yields. Alternatively, the surface of electrode plate 25 may be machined or treated to increase the probability of ion incidence and/or the electrode plate may be heated to its maximum thermal stability. By heating the electrode plate, the energy of the electrons in the conduction band increases, thereby increasing the probability of an electron being emitted from the surface.

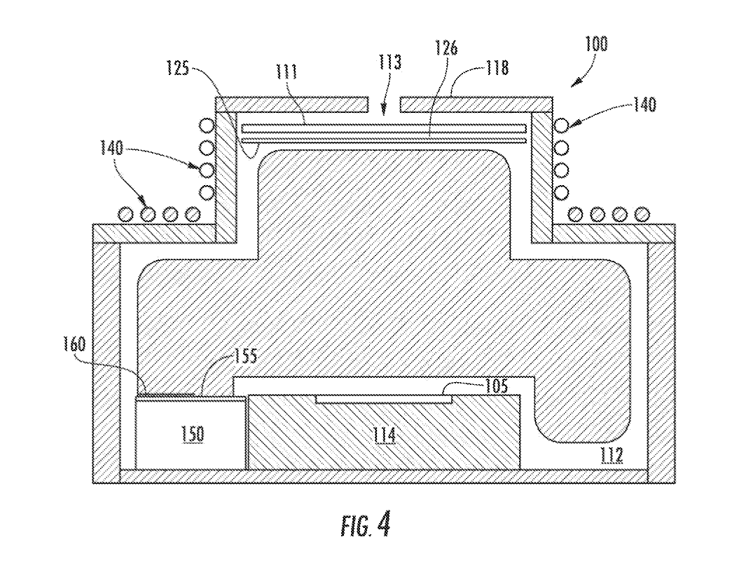

FIG. 4 illustrates a simplified PLAD system 100 which utilizes a closed loop control system in accordance with an exemplary embodiment of the present disclosure. Generally, the system 100 comprises a process chamber 112 having a pedestal or platen 114 to support an insulated target substrate 105. One or more reactive gases containing the desired dopant characteristics are fed into the process chamber 112 via a gas inlet 113 through a top plate 118 of the chamber. A baffle 111 disposed near inlet 113 is used to uniformly distribute the reactive gas(es) introduced into the chamber 112. RF power is supplied to a plurality of vertical coils and horizontal coils 140 disposed around the walls of chamber 112. This RF energy ionizes the source gas supplied to chamber 112 to create plasma 105 having the desired dopant characteristics. A negative bias voltage pulse is applied to the target substrate 105 via the platen 114 to draw charged particles from plasma 120 across a sheath for implantation into the substrate.

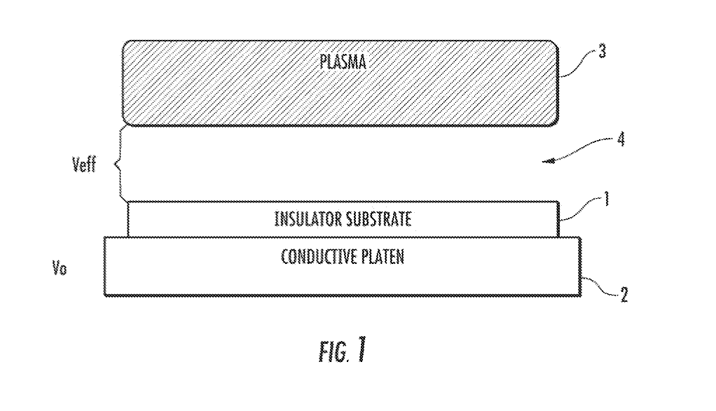

As described above with respect to FIG. 2, a charge build-up occurs on the surface of insulator substrate 105 due to ions implanted into the insulator target substrate and the generation of secondary electrons. In order to control implant depth of the ions generated in plasma 120 into insulator substrate 105, the voltage at the surface of the insulator substrate must be controlled. Electrode 125 is disposed underneath baffle 111 on insulating portion 126 toward plasma 120. Alternatively, electrode 125 may be integrally formed with baffle 111 as described above with respect to FIG. 1. A closed loop control system is disposed in chamber 112 and is defined by shield ring 150, insulating layer 155 and metal layer 160. The closed loop system is used to control the voltage of the insulator target substrate 105 (e.g. glass, quartz, etc.) during an implant process by essentially mimicking the configuration of the insulator substrate 105 and platen 114 and using this measurement to bias the electrode 125 to attract ions from the plasma and control the introduction of secondary electrons toward the substrate to neutralize charge build-up thereon.

In particular, the insulating layer 155 is selected to have the same properties as the insulating substrate 105. The insulating layer 155 is disposed on shield ring 150. Shield ring 150 is electrically connected to and functions as an extension of platen 114. In this manner, the bias voltage pulses applied to platen 114 are likewise applied to shield ring 150. Metal layer 160 is relatively thin, typically 10's of microns thick, and is used to monitor the voltage at the insulator target substrate. This monitored voltage represents the voltage at the surface of the insulator target substrate 105 being implanted. Based on this monitored voltage, the voltage pulses supplied to the electrode plate 125 may be controlled to attract ions from plasma 120. This in turn determines the generation of secondary electrons used to neutralize the charge build-up on the surface of insulator substrate 105.

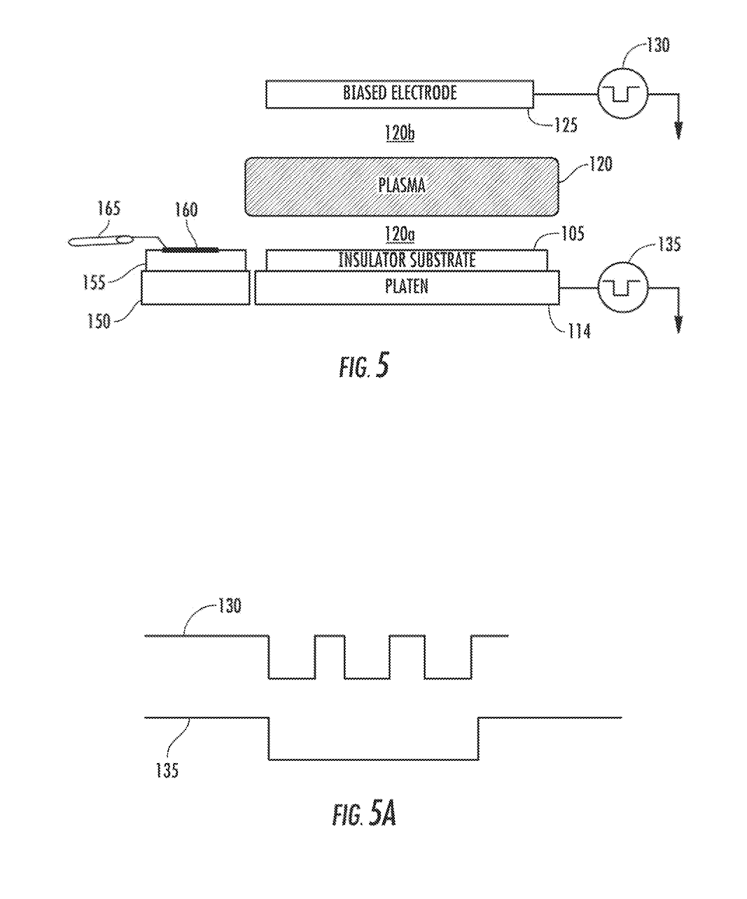

FIG. 5 is a functional diagram showing just the interior of PLAD tool 100 with the closed loop control system. Platen 114 is configured to support target insulator substrate 105. Electrode plate 125 is opposite the cathode formed by platen 114 and target insulator substrate 105. Electrode plate 125 is negatively biased with a voltage pulse 130. The pulse 130 is synchronized with the bias voltage pulses 135 applied to platen 114 used to attract the ions from plasma 120 across sheath 120a into insulator substrate 105.

The closed loop system includes shield ring 150 which is an extension of, and electrically connected to platen 114. Insulator 155 is disposed on shield ring 150 around the periphery of insulator substrate 105. This allows the same bias voltage applied to platen 114 to also be applied to shield ring 150 and consequently, insulator 155. By disposing the shield ring and insulator around the periphery of platen 114 and target insulator substrate 105 respectively, the closed loop system mimics the implant process received by substrate 105. Metal layer 160 is disposed on insulator 155 and a voltage monitor (probe) 165 is connected thereto to measure the surface voltage on insulator 155. This measured voltage on the surface of insulator 155 is understood to be the charge build-up generated on the surface of insulator substrate 105 since the insulator 155 is disposed around the periphery of substrate 105. Based on the measured voltage on the surface of insulator 155, the voltage pulses 130 applied to electrode 125 may be adjusted and/or controlled such that number of secondary electrons generated by ions that strike the surface of electrode 125 is sufficient to obtain the desired voltage on the surface of insulator target substrate 105.

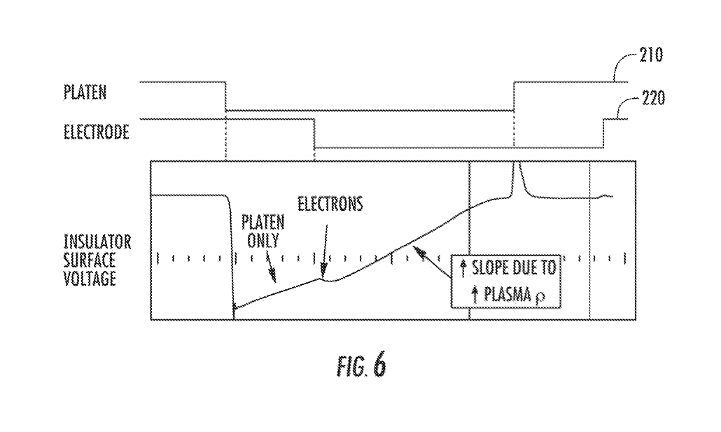

FIG. 6 illustrates the effect of a single pulse 130 applied to electrode 125 which is offset from pulse 135 applied to platen 114 and substrate 105 for explanatory purposes. The pulses are shown as being offset by 5 μS to illustrate the impact of the electrode bias voltage on the build-up of surface charge. As can be seen, when the bias voltage pulse 210 is applied to platen 114, the surface voltage on insulator 105 decreases. When the bias voltage pulse 220 is applied to electrode 125, secondary electrons are generated by the striking of ions on the surface of electrode 125. As can be seen, the surface voltage on insulator 105 increases with a positive slope until the voltage pulse 210 ends and the surface voltage of insulator 105 spikes and levels off for the remainder of electrode pulse 220.

In addition, the width of the voltage pulses 130 applied to electrode plate 125 may be adjusted to provide a longer pulse to attract ions toward the plate thereby increasing the number of secondary electrons generated. Moreover, a plurality of voltage pulses applied to the electrode 125 may occur within the timing of one pulse applied to the substrate. In particular, FIG. 5a illustrates a plurality of voltage pulses 130 applied to the electrode plate 125 that occur within the timing of pulse 135 applied to the insulator substrate 105. The width, duration, voltage level and number of pulses applied controls the voltage build-up on the surface of the substrate.

Alternatively, the temperature of the electrode 125 may be controlled which impacts the number of secondary electrons generated when ions strike the surface. This may be used as an initial control to neutralize charge build-up on the surface of the substrate without the use of the control loop system comprised of the shield ring 150, insulator 155 and metal layer 160. In this manner, once the initial control of the charge build-up on the surface of the substrate is managed by changing the temperature of electrode 125, then the closed loop control system may be used to fine tune the generation of secondary electrons and neutralize charge build-up.

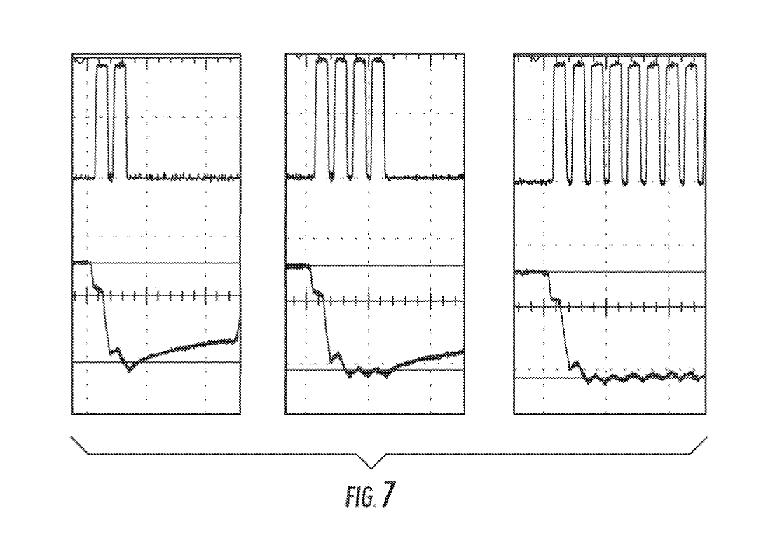

FIG. 7 includes graphs illustrating the frequency of pulses and the corresponding impact on the surface voltage of insulator 105. As can be seen, as the frequency of pulses applied to electrode 125 increases, a relatively constant surface voltage on insulator 105 can be maintained.

While the present invention has been disclosed with reference to certain embodiments, numerous modifications, alterations and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

What is claimed is:

1. A plasma processing tool comprising:
a plasma chamber configured to generate a plasma having ions from a gas introduced into the chamber;
a platen configured to support and electrically connect to an insulator substrate for plasma doping, said platen connected to a voltage source supplying negative bias voltage pulses at a first potential to said platen and said substrate;
an electrode disposed above said generated plasma, said electrode receiving negative bias voltage pulses at a second potential, said second potential being greater than said first potential wherein said ions strike a surface of said electrode which generates secondary electrons, said secondary electrons accelerated toward said substrate at said second potential to neutralize charge build-up on said substrate.

2. The plasma processing tool of claim 1 further comprising:
a baffle disposed above said electrode a distance away from said platen; and
an insulating portion disposed between said baffle and said electrode to electrically isolate said electrode.

3. The plasma processing tool of claim 1 wherein said electrode is an electrode plate having a first surface, said surface directed toward said platen, said first surface having a profile configured to increase an incident angle associated with said ions on said electrode.

4. A method of neutralizing charge build-up on a surface of an insulator target substrate in a plasma processing tool comprising:
providing a reactive gas to a chamber;
exciting the reactive gas to generate a plasma having ions;
applying first bias voltage pulses to an insulator substrate disposed in said chamber;
applying second bias voltage pulses to an electrode disposed above said plasma, said second bias voltage pulses having a higher potential than said first bias voltage pulses to attract said ions toward said electrode;
generating secondary electrons when said attracted ions strike a surface of said electrode; and
accelerating said generated secondary electrons toward said insulator substrate to neutralize charge build-up present on a surface of said substrate.

5. The method of claim 4 wherein said second bias voltage pulses are negative and said first and second bias voltage pulses are synchronized.

6. The method of claim 4 wherein the secondary electrons are accelerated toward said insulator substrate at a potential corresponding to the second bias voltage pulses.

7. The method of claim 6 further comprising decelerating the secondary electrons before said secondary electrons reach the surface of said insulator substrate.

8. The method of claim 4 further comprising heating said electrode before applying the second bias voltage pulses.

9. The method of claim 4 further comprising distributing said reactive gas within said chamber via a baffle disposed above said insulator substrate, said electrode disposed on a side of said baffle directed toward the insulator substrate.

10. An apparatus for monitoring plasma immersion ion implantation comprising;
a plasma chamber configured to generate a plasma having ions from a gas introduced into the chamber;
a platen configured to support and electrically connect to an insulator substrate for implanting said ions therein, said platen connected to a voltage source supplying negative bias voltage pulses at a first potential to said platen and said substrate;
a shield ring disposed within said chamber contiguous with said platen, said shield ring electrically connected to said platen and biased at said first potential;
an insulator disposed on said shield ring;
a metal layer disposed on said insulator, said metal layer having a charge corresponding to a charge build-up of said substrate during implantation of said ions therein; and
a probe connected to said metal layer for measuring said charge build-up.

11. The apparatus of claim 10 further comprising an electrode disposed above said generated plasma, said electrode receiving negative bias voltage pulses at a second potential, said second potential being greater than said first potential to attract said ions from said plasma and generate secondary electrons which are accelerated toward said substrate at said second potential to neutralize charge build-up on said substrate.

12. A method for regulating surface voltage of an insulator substrate undergoing plasma immersion ion implantation comprising:
exciting a reactive gas to generate a plasma having ions within a plasma chamber;
monitoring the voltage of a surface of an insulator substrate disposed on a platen within the plasma chamber;
adjusting one of a plurality of parameters associated with an electrode disposed above the plasma generated within said chamber;
attracting ions from said generated plasma toward said electrode;
generating secondary electrons when said ions strike said electrode; and
directing said generated secondary electrons toward said substrate to regulate the voltage on the surface of said substrate.

13. The method of claim 12 wherein adjusting one of a plurality of parameters associated with an electrode comprises adjusting a bias voltage of said electrode;

14. The method of claim 12 wherein adjusting one of a plurality of parameters associated with an electrode comprises adjusting a width of a voltage pulse applied to said electrode.

15. The method of claim 12 further comprising applying a biasing voltage pulse to said insulator substrate, wherein adjusting one of a plurality of parameters associated with an electrode comprises adjusting the number of bias voltage pulses applied to said electrode during each of said pulse voltage pulses applied to said insulator substrate.
